(19) United States
(12) Patent Application Publication
(10) Pub. No.: US 2026/0121641 A1
(43) Pub. Date: Apr. 30, 2026

(54) MULTIPLEXER AND LEAKAGE CURRENT CONTROL METHOD

(71) Applicant: SigmaStar Technology Ltd., Xiamen (CN)

(72) Inventors: Zili YU, Shanghai (CN); Zhun CHEN, Shanghai (CN); Chengqi HUANG, Shanghai (CN)

(21) Appl. No.: 19/332,280

(22) Filed: Sep. 18, 2025

(30) Foreign Application Priority Data
Oct. 24, 2024 (CN) 202411493223.6

(51) Int. Cl. H03K 19/003; H03K 19/00; H03K 19/173

(52) U.S. Cl. CPC H03K 19/00361; H03K 19/0013; H03K 19/0027; H03K 19/1737

(57) ABSTRACT

A multiplexer includes first and second selection circuits and a leakage current control circuit. The first selection circuit is selectively turned on according to a first selection signal to transmit a first input signal to an output node to generate an output voltage. The second selection circuit includes first and second switches. The first switch is selectively turned on according to a second selection signal, and the second switch is turned on according to first and second control signals to transmit a second input signal to the output node when the first switch is turned on. The leakage current control circuit compares the output voltage with a plurality of reference voltages to generate a plurality of detection signals when the first selection circuit is turned on, and selectively adjusts a level of the first or the second control signal according to the detection signals and the second selection signal.

This application claims the benefit of China application Serial No. CN202411493223.6, filed on October 24, 2024, the subject matter of which is incorporated herein by reference.

### BACKGROUND OF THE INVENTION

### Field of the Invention

The present application relates to a multiplexer, and more particularly to a multiplexer able to perform leakage current control according to a current output of the multiplexer and a leakage current control method thereof.

### Description of the Related Art

Multiplexers are often applied in various electronic devices to support multi-channel or multi-input usage requirements. Each channel is configured with a corresponding switch circuit to implement a selection function. In actual applications, a switch circuit is usually implemented by one or more transistors. Along with the advancement of processes, dimensions of transistors are also constantly decreased such that the issue of leakage currents may become increasingly severe. In particular, when reverse bias voltages of any two terminals of a transistor are rather large, influences brought by leakage currents are caused at these two terminals of the transistor. In actual applications, if leakage currents occur in transistors in the multiple channels that are not selected by a multiplexer, these leakage currents may lead to deviations (which increase as the number of channels increases) of an output of the multiplexer, resulting in an inaccurate output of the multiplexer.

### SUMMARY OF THE INVENTION

In some embodiments, it is an object of the present application to provide a multiplexer able to perform leakage current control according to a current output of the multiplexer and a leakage current control method thereof so as to improve the issues of the prior art.

In some embodiments, a multiplexer includes first selection circuit, a second selection circuit and a leakage current control circuit. The first selection circuit is selectively turned on according to a first selection signal to transmit a first input signal to an output node to generate an output voltage. The second selection circuit includes a first switch and a second switch. The first switch is selectively turned on according to a second selection signal, and the second switch is turned on according to a first control signal and a second control signal to transmit a second input signal to the output node when the first switch is turned on. The leakage current control circuit compares the output voltage with a plurality of reference voltages to generate a plurality of detection signals when the first selection circuit is turned on, and selectively adjusts a level of the first or the second control signal according to the plurality of detection signals and the second selection signal.

In some embodiments, a leakage current control method is applied to a multiplexer. The multiplexer includes a first selection circuit, a second selection circuit and a leakage current control circuit. The method includes operations of: selectively turning on the first selection circuit according to a first selection signal to transmit a first input signal to an output node to generate an output voltage; selectively turning on a first switch of the second selection circuit according to a second selection signal, and turning on a second switch of the second selection circuit according to a first control signal and a second control signal to transmit a second input signal to the output node when the first switch is turned on; and comparing the output voltage with a plurality of reference voltages to generate a plurality of detection signals, and selectively adjusting a level of the first control signal or the second control signal according to the plurality of detection signals and the second selection signal.

Features, implementations and effects of the present application are described in detail in preferred embodiments with the accompanying drawings below.

### BRIEF DESCRIPTION OF THE DRAWINGS

To better describe the technical solution of the embodiments of the present application, drawings involved in the description of the embodiments are introduced below. It is apparent that, the drawings in the description below represent merely some embodiments of the present application, and other drawings apart from these drawings may also be obtained by a person skilled in the art without involving inventive skills.

FIG. 1 shows a schematic diagram of a multiplexer according to some embodiments of the present application.

FIG. 2 shows a schematic diagram of the selection circuit in FIG. 1 according to some embodiments of the present application.

FIG. 3 shows a schematic diagram of the leakage current control circuit in FIG. 1 according to some embodiments of the present application.

FIG. 4 shows a flowchart of a leakage current control method according to some embodiments of the present application.

### DETAILED DESCRIPTION OF THE INVENTION

All terms used in the literature have commonly recognized meanings. Definitions of the terms in commonly used dictionaries and examples discussed in the disclosure of the present application are merely exemplary, and are not to be construed as limitations to the scope or the meanings of the present application. Similarly, the present application is not limited to the embodiments enumerated in the description of the application.

The term “coupled” or “connected” used in the literature refers to two or multiple elements being directly and physically or electrically in contact with each other, or indirectly and physically or electrically in contact with each other, and may also refer to two or more elements operating or acting with each other. As given in the literature, the term “circuit” may be a device connected by at least one transistor and/or at least one active element by a predetermined means so as to process signals.

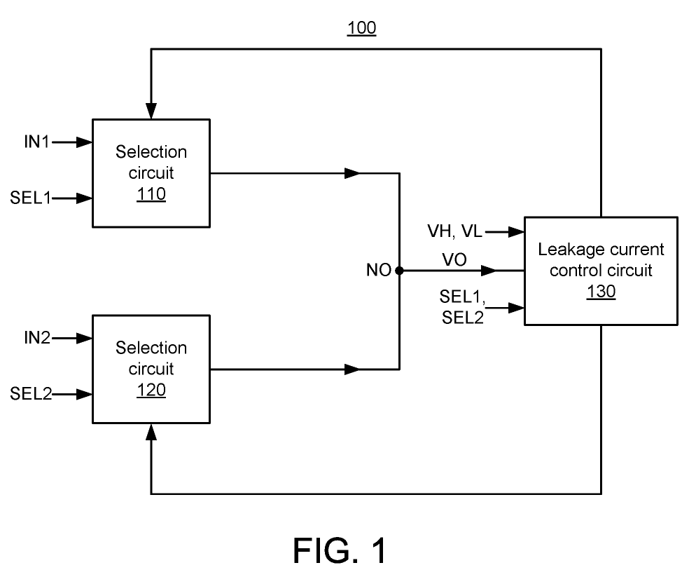

FIG. 1 shows a schematic diagram of a multiplexer 100 according to some embodiments of the present application. The multiplexer 100 includes selection circuit 110, a selection circuit 120 and a leakage current control circuit 130. The selection circuit 110 is selectively turned on according to a selection signal SEL1 to transmit an input signal IN1 to an output node NO to generate an output voltage VO (that is, outputting the input signal IN1 as the output voltage). Similarly, the selection circuit 120 is selectively turned on according to a selection signal SEL2 to transmit an input signal IN2 to the output node NO to generate the output voltage VO. In some embodiments, the selection circuit 110 and the selection circuit 120 may have the same circuit structure; however, the present application is not limited to such example.

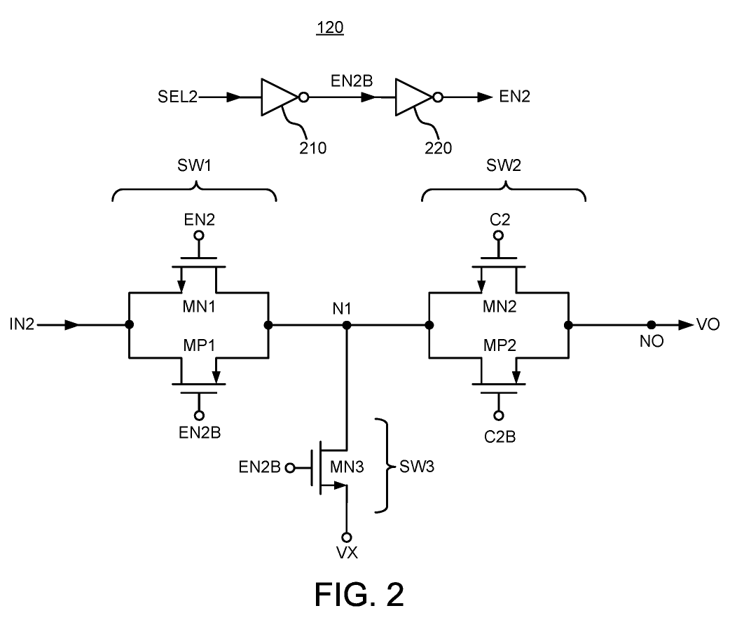

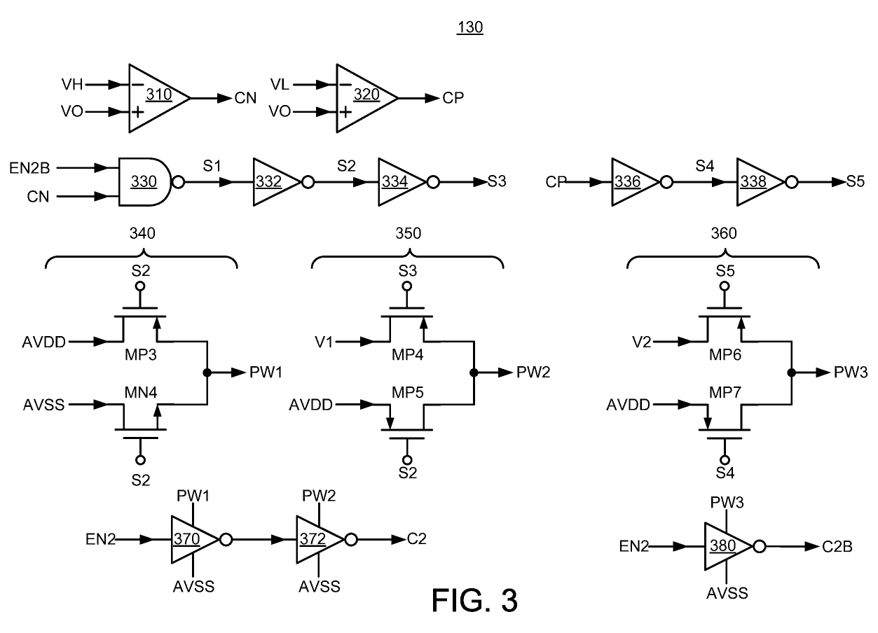

The leakage current control circuit 130 may compare the output voltage VO with multiple reference voltages VL and VH when one of the selection circuit 110 and the selection circuit 120 is turned on to generate multiple detection signals (for example, the detection signal CP and the detection signal CN in FIG. 3), and selectively adjust, according to a corresponding one of the selection signal SEL1 and the selection signal SEL2 and these detection signals, a level of a control signal (for example, the control signal C2 and the control signal C2B in FIG. 2 or FIG. 3) that is input to the other (that is, the selection circuit that is not turned on) of the selection circuit 110 and the selection circuit 120, so as to reduce a leakage current in the selection circuit that is not turned on and prevent any leakage current from affecting the level of the output voltage VO.

FIG. 2 shows a schematic diagram of the selection circuit 120 in FIG. 1 according to some embodiments of the present application. The selection circuit 120 includes a switch SW1, a switch SW2 and a switch SW3. The switch SW1 is selectively turned on according to the selection signal SEL2 to transmit the input signal IN2 to a node N1. The switch SW2 is selectively turned on according to the control signal C2 and the control signal C2B to transmit the input signal IN2 to the output node NO when the switch SW1 is turned on.

More specifically, the switch SW1 includes a P-type transistor MP1 and an N-type transistor MN1. A first terminal (for example, the source) of the N-type transistor MN1 and a first terminal (for example, the drain) of the P-type transistor MP1 receive the input signal IN2, a second terminal (for example, the drain) of the N-type transistor MN1 and a second terminal (for example, the source) of the P-type transistor MP1 are coupled to the node N1. A control terminal (for example, the gate) of the N-type transistor MN1 receives a switching signal EN2, and a control terminal (for example, the gate) of the P-type transistor MP1 receives a switching signal EN2B. In some embodiments, the switching signal EN2 and the switching signal EN2B are associated with the selection signal SEL2. For example, the switching signal EN2B may be a logical inverse of the selection signal SEL2, and the switching signal EN2 may be a logical inverse of the switching signal EN2B. In some embodiments, the selection circuit 120 may further include an inverter 210 and an inverter 220. The inverter 210 may generate the switching signal EN2B according to the selection signal SEL2, and the inverter 220 may generate the switching signal EN2 according to the switching signal EN2B. With the configuration above, when the selection signal SEL2 is logic 1, it means that the multiplexer 100 turns on the selection circuit 120 to selectively output the input signal IN2 as the output voltage VO through the selection circuit 120. In this condition, the switching signal EN2B is logic 0, and the switching signal EN2 is logic 1, so that the P-type transistor MP1 and the N-type transistor MN1 are turned on (that is, the switch SW1 is turned on) to transmit the input signal IN2 to the node N1.

Similarly, the switch SW2 includes a P-type transistor MP2 and an N-type transistor MN2. A first terminal of the N-type transistor MN2 and a first terminal of the P-type transistor MP2 are coupled to the node N1, and a second terminal of the N-type transistor MN2 and a second terminal of the P-type transistor MP2 are coupled to the output node NO to output the output voltage VO. A control terminal of the N-type transistor MN2 receives the control signal C2, and a control terminal of the P-type transistor MP2 receives the control signal C2B. In some embodiments, the control signal C2 and the control signal C2B are associated with the selection signal SEL2 and may be generated by the leakage current control circuit 130. For example, when the switch SW1 is turned off according to the selection signal SEL2, the P-type transistor MP2 and the N-type transistor MN2 are turned off according to the control signal C2B and the control signal C2, respectively. Alternatively, when the switch SW1 is turned on according to the selection signal SEL2, the P-type transistor MP2 and the N-type transistor MN2 are turned on according to the control signal C2B and the control signal C2, respectively, to transmit the input signal IN2 to the output node NO and accordingly generate the output voltage VO.

The switch SW3 may be implemented by an N-type transistor MN3; however, the present application is not limited to such example. More specifically, a first terminal of the switch SW3 is coupled to the node N1, a second terminal of the switch SW3 receives a predetermined voltage VX, and a control terminal of the switch SW3 receives the switching signal EN2B. Thus, the switch SW3 may be turned on according to the switching signal EN2B (that is, a logical inverse of the selection signal SEL2) to transmit the predetermined voltage VX to the node N1. When neither of the switch SW1 nor the switch SW2 is turned on (that is, the selection circuit 120 is not selected), the switch SW3 of the selection circuit 120 may be turned on accordingly to transmit the predetermined voltage VX to the node N1, so that the voltage across two terminals of the switch SW2 does not become overly high. Thus, a leakage current between the drain and the source of the transistor (for example, including the P-type transistor MP2 and the N-type transistor MN2) in the switch SW2 may be reduced. In some embodiments, a level of the predetermined voltage VX may be determined according to an input range of the multiplexer 100. For example, the level of the predetermined voltage VX may be set to be one-half of the highest level of the input signal IN1 (or the input signal IN2); however, the present application is not limited to such example.

FIG. 3 shows a schematic diagram of the leakage current control circuit 130 in FIG. 1 according to some embodiments of the present application. The leakage current control circuit 130 includes a comparator 310, a comparator 320, a logic gate 330, an inverter 332, an inverter 334, an inverter 336, an inverter 338, a switching circuit 340, a switching circuit 350, a switching circuit 360, an inverter 370, an inverter 372 and an inverter 380.

The comparator 310 compares the output voltage VO with the reference voltage VH to generate a detection signal CN. The comparator circuit 320 compares the output voltage VO with the reference voltage VL to generate a detection signal CP. For example, when the selection circuit 110 is selected and is turned on, the selection circuit 110 outputs the input signal IN1 as the output voltage VO. The comparator 310 may compare the output voltage VO with the reference voltage VH to determine whether the output voltage VO (equivalent to the input signal IN1) at this point is higher than the reference voltage VH to generate the corresponding detection signal CN. Similarly, the comparator 320 may compare the output voltage VO with the reference voltage VL to determine whether the output voltage VO (equivalent to the input signal IN1) at this point is lower than the reference voltage VL to generate the corresponding detection signal CP. In some embodiments, the comparator 310 and the comparator 320 may be continuous time comparators. In some other embodiments, the comparator 310 and the comparator 320 may be non-continuous time comparators, which may perform comparison within a specific period of time according to a clock signal (not shown) to reduce the overall power consumption.

In some embodiments, the reference voltage VH is the highest reference voltage among the reference voltage VH and the reference voltage VL, and the reference voltage VL is the lowest reference voltage among the reference voltage VH and the reference voltage VL. In some embodiments, the reference voltage VH may be set to be approximately two-thirds of a highest power supply voltage (for example, a power supply voltage AVDD to be described below) in the system, and the reference voltage VL may be set to be approximately one-third of the highest power supply voltage; however, the present application is not limited to such examples.

The logic gate 330 generates a signal S1 according to the switching signal EN2B and the detection signal CN. In some embodiments, the logic gate 330 may be, for example but not limited to, a NAND gate. The inverter 332 generates a switching signal S2 according to the signal S1. The inverter 334 generates a switching signal S3 according to the switching signal S2. In other words, the switching signal S2 is a logical inverse of the signal S1, and the switching signal S3 is a logical inverse of the switching signal S2. The switching circuit 340 outputs the power supply voltage AVDD or the power supply voltage AVSS as a supply voltage PW1 according to the switching signal S2, wherein the power supply voltage AVDD is higher than the power supply voltage AVSS. More specifically, the switching circuit 340 includes a P-type transistor MP3 and an N-type transistor MN4. A first terminal of the P-type transistor MP3 receives the power supply voltage AVDD, a second terminal of the P-type transistor MP3 is coupled to a second terminal of the N-type transistor MN4 to output the supply voltage PW1, and a control terminal of the P-type transistor MP3 receives the switching signal S2. A first terminal of the N-type transistor MN4 receives the power supply voltage AVSS, and a control terminal of the N-type transistor MN4 receives the switching signal S2.

The switching circuit 350 outputs the voltage V1 or the power supply voltage AVDD as a supply voltage PW2 according to the switching signal S3 and the switching signal S2. More specifically, the switching circuit 350 may include a P-type transistor MP4 and a P-type transistor MP5. A first terminal of the P-type transistor MP4 receives the voltage V1, a second terminal of the P-type transistor MP4 is coupled to a second terminal of the P-type transistor MP5 to output the supply voltage PW2, and a control terminal of the P-type transistor MP4 receives the switching signal S3. A first terminal of the P-type transistor MP5 receives the power supply voltage AVDD, and a control terminal of the P-type transistor MP5 receives the switching signal S2. In some embodiments, the voltage V1 is set to be higher than the power supply voltage AVSS.

The inverter 336 generates a switching signal S4 according to the detection signal CP, and the inverter 338 generates a switching signal S5 according to the switching signal S4. In other words, the switching signal S4 is a logical inverse of the detection signal CP, and the switching signal S5 is a logical inverse of the switching signal S4. The switching circuit 360 outputs the voltage V2 or the power supply voltage AVDD as a supply voltage PW3 according to the switching signal S4 and the switching signal S5. More specifically, the switching circuit 360 may include a P-type transistor MP6 and a P-type transistor MP7. A first terminal of the P-type transistor MP6 receives the voltage V2, a second terminal of the P-type transistor MP6 is coupled to a second terminal of the P-type transistor MP7 to output the supply voltage PW3, and a control terminal of the P-type transistor MP6 receives the switching signal S5. A first terminal of the P-type transistor MP7 receives the power supply voltage AVDD, and a control terminal of the P-type transistor MP7 receives the switching signal S4. In some embodiments, the voltage V2 is set to be lower than the power supply voltage AVDD.

The inverter 370 is coupled in series with the inverter 372, and generates the control signal C2 according to the switching signal EN2. For example, the inverter 370 is powered by the supply voltage PW1 and the power supply voltage AVSS to generate a corresponding output according to the switching signal EN2. The inverter 372 is powered by the supply voltage PW2 and the power supply voltage AVSS and generates the control signal C2 according to an output of the inverter 370. Similarly, the inverter 380 generates the control signal C2B according to the switching signal EN2. For example, the inverter 380 is powered by the supply voltage PW3 and the power supply voltage AVSS to generate the control signal C2B according to the switching signal EN2.

Related operations of the leakage current control circuit 130 are sequentially described below according to different comparison results of the output voltage VO with respect to the reference voltage VL and the reference voltage VH. In a first scenario, when the output voltage VO is higher than the reference voltage VL but lower than the reference voltage VH (that is, the input signal IN1 transmitted by the selected selection circuit 110 is between the reference voltage VL and the reference voltage VH), according to the detection signal CP, the detection signal CN and the selection signal SEL2, the leakage current control circuit 130 does not adjust the level of the control signal C2 or the control signal C2B. In other words, in the first scenario, the leakage current control circuit 130 outputs the control signal C2B having a first predetermined level (for example, the highest power supply voltage AVDD in the system) and the control signal C2 having a second predetermined level (for example, the lowest power supply voltage AVSS in the system).

More specifically, when the output voltage VO is between the reference voltage VL and the reference voltage VH, the detection signal CP is logic 1, and the detection signal CN is logic 0. Under this condition, the signal S1 is logic 1, such that the switching signal S2 is logic 0, the switching signal S3 is logic 1, the switching signal S4 is logic 0, and the switching signal S5 is logic 1. Thus, the switching circuit 340 outputs the power supply voltage AVDD as the supply voltage PW1, the switching circuit 350 outputs the power supply voltage AVDD as the supply voltage PW2, and the switching circuit 360 outputs the power supply voltage AVDD as the supply voltage PW3, so that the inverter 372 generates the control signal C2B having the first predetermined level and the inverter 380 generates the control signal C2 having the second predetermined level.

In a second scenario, when the output voltage VO is higher than the reference voltage VH (that is, the input signal IN1 transmitted by the selected selection circuit 110 is higher than the reference voltage VH), the leakage current control circuit 130 increases the level of the control signal C2 (compared to the second predetermined level above) according to the detection signal CP, the detection signal CN and the selection signal SEL2. More specifically, when the output voltage VO is higher than the reference voltage VH, the detection signal CP is logic 1, and the detection signal CN is logic 1. Under this condition, the signal S1 is logic 0, such that the switching signal S2 is logic 1, the switching signal S3 is logic 0, the switching signal S4 is logic 0, and the switching signal S5 is logic 1. Thus, the switching circuit 340 outputs the power supply voltage AVSS as the supply voltage PW1, the switching circuit 350 outputs the voltage V1 as the supply voltage PW2, and the switching circuit 360 outputs the power supply voltage AVDD as the supply voltage PW3. Accordingly, the inverter 372 outputs the control signal C2B having a level as that of the voltage V1 to reduce a reverse bias voltage between the gate and the drain (or source) of the N-type transistor MN2 in the selection circuit 120 in FIG. 2, thereby reducing a bulk leakage current of the N-type transistor MN2.

In a third scenario, when the output voltage VO is lower than the reference voltage VL (that is, the input signal IN1 transmitted by the selected selection circuit 110 is lower than the reference voltage VL), the leakage current control circuit 130 decreases the level of the control signal C2B (compared to the first predetermined level above) according to the detection signal CP, the detection signal CN and the selection signal SEL2. More specifically, when the output voltage VO is lower than the reference voltage VL, both of the detection signal CP and the detection signal CN are logic 0. Under this condition, the signal S1 is logic 1, such that the switching signal S2 is logic 0, the switching signal S3 is logic 1, the switching signal S4 is logic 1, and the switching signal S5 is logic 0. Thus, the switching circuit 340 outputs the power supply voltage AVDD as the supply voltage PW1, the switching circuit 350 outputs the power supply voltage AVDD as the supply voltage PW2, and the switching circuit 360 outputs the voltage V2 as the supply voltage PW3. Accordingly, the inverter 380 outputs the control signal C2B having a level as that of the voltage V2 to reduce a reverse bias voltage between the gate and the drain (or source) of the P-type transistor MP2 in the selection circuit 120 in FIG. 2, thereby reducing the bulk leakage current of the P-type transistor MP2.

On the other hand, if the selection circuit 120 is selected (that is, when the selection signal SEL2 is switched to logic 1), the switching signal EN2B is logic 0 and the switching signal EN2 is logic 1. Under this condition, the level of the control signal C2B is fixed at that of the power supply voltage AVDD, and the level of the control signal C2 is fixed at that of the power supply voltage AVSS (or ground).

On the basis of the operations above, it is understandable that, the leakage current control circuit 130 is able to adjust, according to a current output of the multiplexer 100, the level of a control signal (for example, the control signal C2B and the control signal C2) used by other channels that are not selected, thereby reducing the sizes of leakage currents of the other channels that are not selected to prevent the leakage currents from affecting the output voltage VO.

For clear and concise description purposes, the circuits shown in FIG. 3 are primarily for illustrating parts of related circuits for controlling the selection circuit 120. It should be understood that, the leakage current control circuit 130 may further include parts of related circuits for controlling the selection circuit 110. In other words, the leakage current control circuit 130 may further additionally include a logic gate 330, an inverter 332, an inverter 334, an inverter 336, an inverter 338, a switching circuit 340, a switching circuit 350, a switching circuit 360, an inverter 370, an inverter 372 and an inverter 380, so as to perform leakage current control on the selection circuit 110. In some embodiments, in the leakage current control circuit 130, parts of related circuits for controlling the selection circuit 110 and parts of related circuits for controlling the selection circuit 120 share the same set of the comparator 310 and the comparator 320.

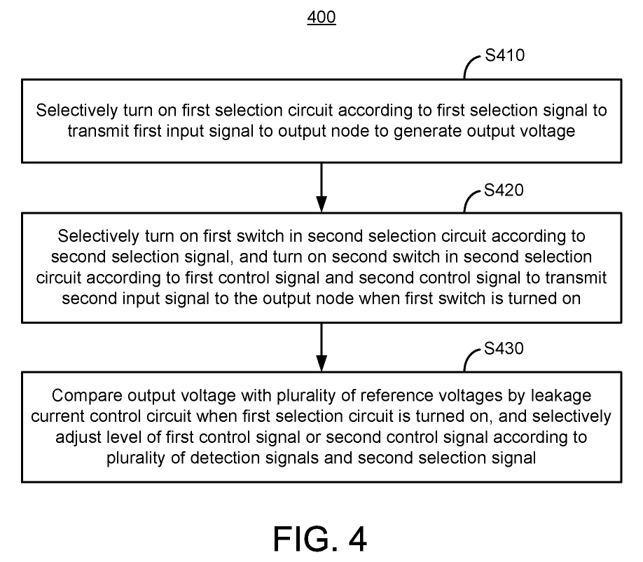

FIG. 4 shows a flowchart of a leakage current control method 400 according to some embodiments of the present application. In some embodiments, the leakage current control method 400 may be performed by, for example but not limited to, the multiplexer 100 in FIG. 1.

In operation S410, a first selection circuit is selectively turned on according to a first selection signal to transmit a first input signal to an output node to generate an output voltage. In operation S420, a first switch of a second selection circuit is selectively turned on according to a second selection signal, and a second switch of the second selection circuit is turned on according to a first control signal and a second control signal to transmit a second input signal to the output node when the first switch is turned on. In operation S430, when the first selection circuit is turned on, the output voltage is compared with a plurality of reference voltages by a leakage current control circuit to generate a plurality of detection signals, and a level of the first control signal or the second control signal is selectively adjusted according to the plurality of detection signals and the second selection signal.

Details associated with the multiple operations of the leakage current control method 400 above may be referred to from the details of the multiple embodiments above, and such repeated details are omitted herein for brevity. The multiple operations above are merely examples, and are not limited to being performed in the order specified in this example. Without departing from the operation means and ranges of the various embodiments of the present application, additions, replacements, substitutions or omissions may be made to the operations of the leakage current control method 400, or the operations may be performed in different orders. Alternatively, all or some of one or more the operations of the leakage current control method 400 may be performed simultaneously.

In conclusion, the multiplexer and the leakage current control method provided according to some embodiments of the present application are able to perform leakage current control on circuits in a channel that is not selected in the multiplexer according to a current output of the multiplexer, so as to prevent a leakage current of the circuit in the channel that is not selected from affecting an output of the multiplexer. Thus, the output accuracy of the multiplexer can be improved.

While the present application has been described by way of example and in terms of the preferred embodiments, it is to be understood that the disclosure is not limited thereto. Various modifications may be made to the technical features of the present application by a person skilled in the art on the basis of the explicit or implicit disclosures of the present application. The scope of the appended claims of the present application therefore should be accorded with the broadest interpretation so as to encompass all such modifications.

What is claimed is:

1. A multiplexer, comprising:
a first selection circuit, selectively turned on according to a first selection signal to transmit a first input signal to an output node to generate an output voltage;
a second selection circuit, comprising a first switch and a second switch, the first switch selectively turned on according to a second selection signal, and the second switch turned on according to a first control signal and a second control signal to transmit a second input signal to the output node when the first switch is turned on; and
a leakage current control circuit, comparing the output voltage with a plurality of reference voltages to generate a plurality of detection signals when the first selection circuit is turned on, and selectively adjusting a level of the first control signal or the second control signal according to the plurality of detection signals and the second selection signal.

2. The multiplexer according to claim 1, wherein the second switch comprises:
a P-type transistor, turned on according to the first control signal to receive the second input signal when the first switch is turned on; and
an N-type transistor, turned on according to the second control signal to receive the second input signal when the first switch is turned on.

3. The multiplexer according to claim 2, wherein when the output voltage is higher than a highest reference voltage of the plurality of reference voltages, the leakage current control circuit increases a level of the second control signal according to the plurality of detection signals and the second selection signal.

4. The multiplexer according to claim 2, wherein when the output voltage is lower than a lowest reference voltage of the plurality of reference voltages, the leakage current control circuit decreases a level of the first control signal according to the plurality of detection signals and the second selection signal.

5. The multiplexer according to claim 2, wherein when the output voltage is within the plurality of reference voltages, the leakage current control circuit outputs the first control signal having a first predetermined level and the second control signal having a second predetermined level according to the plurality of detection signals and the second selection signal, the first predetermined level is a level of a highest power supply voltage and the second predetermined level is a level of lowest power supply voltage.

6. The multiplexer according to claim 1, wherein the leakage current control circuit comprises:
a first comparator, comparing the output voltage with a first reference voltage of the plurality of reference voltages to generate a first detection signal of the plurality of detection signals; and
a second comparator, comparing the output voltage with a second reference voltage of the plurality of reference voltages to generate a second detection signal of the plurality of detection signals.

7. The multiplexer according to claim 1, wherein the leakage current control circuit comprises:
a logic gate, generating a first signal according to a first switching signal and a first detection signal of the plurality of detection signals, wherein the first switching signal is a logical inverse of the second selection signal;
a first switching circuit, outputting a first power supply voltage or a second power supply voltage as a first supply voltage according to a second switching signal, wherein the second switching signal is a logical inverse of the first signal and the first power supply voltage is higher than the second power supply voltage;
a second switching circuit, outputting a first voltage or the first power supply voltage as a second supply voltage according to a third switching signal and the second switching signal, wherein the third switching signal is a logical inverse of the second switching signal and the first voltage is higher than the second power supply voltage;
a third switching circuit, outputting a second voltage or the first power supply voltage as a third supply voltage according to a fourth switching signal and a fifth switching signal, wherein the fourth switching signal is a logical inverse of a second detection signal of the plurality of detection signals, the fifth switching signal is a logical inverse of the fourth switching signal, and the second voltage is lower than the first power supply voltage;
a plurality of first inverters, coupled in series and generating the first control signal according to a sixth switching signal, wherein the sixth switching signal is a logical inverse of the first switching signal, a first inverter of the plurality of first inverters is powered by the first supply voltage and the second power supply voltage, and a second inverter of the plurality of first inverters is powered by the second supply voltage and the second power supply voltage; and
a second inverter, generating the second control signal according to the sixth switching signal, wherein the second inverter is powered by the third supply voltage and the second power supply voltage.

8. The multiplexer according to claim 1, wherein the second selection circuit further comprises:
a third switch, turned on according to a logical inverse of the second selection signal to transmit a predetermined voltage to a first node, wherein the second switch is coupled between the first node and the output node.

9. The multiplexer according to claim 8, wherein a level of the predetermined voltage is one-half of a highest level of the first input signal.

10. A leakage current control method, applied to a multiplexer, the multiplexer comprising a first selection circuit, a second selection circuit and a leakage current control circuit; the method comprising:
selectively turning on the first selection circuit according to a first selection signal to transmit a first input signal to an output node to generate an output voltage;
selectively turning on a first switch of the second selection circuit according to a second selection signal, and turning on a second switch of the second selection circuit according to a first control signal and a second control signal to transmit a second input signal to the output node when the first switch is turned on; and
comparing the output voltage with a plurality of reference voltages by the leakage current control circuit to generate a plurality of detection signals when the first selection circuit is turned on, and selectively adjusting a level of the first control signal or the second control signal according to the plurality of detection signals and the second selection signal.
